(19) United States
(12) Patent Application Publication
(10) Pub. No.: US 2013/0109128 A1
(43) Pub. Date: May 2, 2013

(54) MANUFACTURING METHOD FOR PHOTOVOLTAIC POWER DEVICE AND MANUFACTURING APPARATUS FOR PHOTOVOLTAIC POWER DEVICE

(71) Applicants: Tomotaka Katsura, Tokyo (JP); Kunihiko NIshimura, Tokyo (JP); Shinya Nishimura, Tokyo (JP); Tatsuki Okamoto, Tokyo (JP); Shuichi Fujikawa, Tokyo (JP)

(72) Inventors: Tomotaka Katsura, Tokyo (JP); Kunihiko NIshimura, Tokyo (JP); Shinya Nishimura, Tokyo (JP); Tatsuki Okamoto, Tokyo (JP); Shuichi Fujikawa, Tokyo (JP)

(73) Assignee: Mitsubishi Electric Corporation, Tokyo (JP)

(21) Appl. No.: 13/698,068

(22) PCT Filed: May 17, 2010
(86) PCT No.: PCT/JP2010/003303

§ 371 Date: Jan. 11, 2013

(51) Int. Cl. H01L 31/18

(52) U.S. Cl. CPC H01L 31/18
USPC 438/71; 156/345.11

(57) ABSTRACT

In order to form a texture structure of inverse pyramid concavities with high speed and accuracy, when a reflection preventing texture is formed on a surface of a photovoltaic power device by laser patterning of an etching resistance film and wet etching, a plurality of laser apertures are machined in a diagonal direction of a square to be a base of the intended pyramid concavity by using a pulse laser and a laser beam splitting means, and a laser aperture pitch between the squares is set to be larger than a pitch on the diagonal.

### TECHNICAL FIELD

The present invention relates to manufacturing methods and manufacturing apparatuses for photovoltaic power devices using crystalline silicon.

### BACKGROUND ART

There is conventionally known a technology in which a minute concavity and convexity structure (texture structure) for reducing the reflectance is formed on a crystalline silicon solar cell surface by laser patterning of an etching resistance film and wet etching. In the laser patterning, a method of splitting a laser beam with a diffractive optical element is employed so that a large number of apertures are formed on the etching resistance film at a high speed (see, for example, Patent Document 1 and Non-Patent Document 1).

### PRIOR ART DOCUMENT

### Patent Document

Patent Document 1: Japanese Unexamined Patent Application Publication No. 2009-147059

### Non-Patent Document

Non-Patent Document 1: D. Niinobe, K. Nishimura, S. Matsuno, H. Fujioka, T. Katsura, T. Okamoto, T. Ishihara, H. Morikawa, and S. Arimoto, “Honeycomb-Structured Multi-Crystalline Silicon Solar Cells With 18.6% Efficiency Via Industrially Applicable Laser Process”, Proceedings of the 23rd EU PVSEC (2008), pages 1824-1828.

### SUMMARY OF INVENTION

### Problem that the Invention is to Solve

In the publicly known prior art disclosed by Patent Document 1 and Non-Patent Document 1, when forming the minute texture structure for reducing the reflectance of the photovoltaic power generation device, one concavity of the texture structure corresponds to one laser aperture of the etching resistance film.

In a process of forming a pyramid texture on a photovoltaic power device using single-crystal silicon, there have been problems of degrading productivity and deteriorating texture size uniformity when using the publicly known prior art. The reason is as follows. In anisotropic etching for forming a pyramid texture, while a pyramid in the texture whose base size is equal to a square circumscribing the laser aperture can be formed by the etching in a short time period, the base size and the depth of the pyramid in the texture grow in a slow speed.

In the publicly known prior art, it is necessary to enlarge a laser aperture diameter or perform etching for long hours in order to form a tightly-arranged pyramid texture. In the former case, there arise problems such as degrading productivity in a laser aperture forming process, deteriorating texture size uniformity due to laser aperture variability, and deteriorating characteristics by residual damage in a wafer generated by a high intensity laser. In the latter case, there arise problems such as degrading productivity in an etching process, and texture size variability caused by increased influence of etching conditions such as the temperature and liquid concentration which vary during the etching for long hours.

### Means for Solving the Problem

A manufacturing method and manufacturing apparatus for a photovoltaic power device according to the present invention is characterized by, when a reflection preventing texture is formed on a surface of a photovoltaic power device using single-crystal silicon by laser patterning of an etching resistance film and wet etching, forming an arrangement of laser apertures with a pattern consisting of at least two different pitch sizes so that one concavity of a texture structure is formed, after machining a plurality of laser apertures in a diagonal direction of a square to be a base of an intended pyramid concavity by using a pulse laser and a laser beam splitting means, from a plurality of laser apertures with a pitch between the squares being set to be larger than a pitch on the diagonal.

### Advantageous Effects of the Invention

According to the present invention, since one concavity of a texture structure is formed from a plurality of relatively small laser apertures, there can be obtained unprecedented and pronounced effects of being able to form a pyramid texture having no size variability with etching in a short time period, while suppressing degradation of productivity in a laser aperture processing and deterioration of texture size uniformity due to aperture shape variability.

### BRIEF DESCRIPTION OF DRAWINGS

FIG. 1 is a diagram for describing an example of a general process for forming a texture structure.

FIG. 2 is a diagram for describing another example of a general process for forming a texture structure.

FIG. 3 is a diagram for describing another example of a general process for forming a texture structure.

FIG. 4 is an example of a pattern of laser aperture portions according to Embodiment 1 of the present invention.

FIG. 5 is a diagram for describing an example of a texture forming process according to Embodiment 1 of the present invention.

FIG. 6 is a diagram for describing another example of a texture forming process according to Embodiment 1 of the present invention.

FIG. 7 is a diagram for describing another example of a texture forming process according to Embodiment 1 of the present invention.

FIG. 8 is a diagram for describing another example of a texture forming process according to Embodiment 1 of the present invention.

FIG. 9 is a schematic configuration diagram of laser machining equipment for forming a laser aperture pattern according to Embodiment 1 of the present invention.

FIG. 10 is a schematic diagram for describing a laser beam splitting pattern according to Embodiment 1 of the present invention.

FIG. 11 is a schematic diagram for describing a laser beam splitting pattern according to Embodiment 2 of the present invention.

FIG. 12 is a schematic diagram for describing a laser beam splitting pattern according to Embodiment 3 of the present invention.

FIG. 13 is a schematic diagram for describing laser pulse timing according to Embodiment 3 of the present invention.

FIG. 14 is a schematic diagram for describing a plane direction of a single-crystal silicon substrate on a silicon substrate conveyance means according to embodiments of the present invention.

FIG. 15 is a schematic diagram for describing a pattern of laser aperture portions according to Embodiment 3 of the present invention.

FIG. 16 is a schematic diagram for describing a texture structure according to Embodiment 3 of the present invention.

FIG. 17 is a schematic diagram for describing a pattern of laser aperture portions according to Embodiment 4 of the present invention.

FIG. 18 is a schematic diagram for describing a pattern of laser aperture portions according to Embodiment 5 of the present invention.

FIG. 19 is a schematic configuration diagram of laser machining equipment for forming a laser aperture pattern according to Embodiment 5 of the present invention.

FIG. 20 is a diagram for describing a texture forming process according to Embodiment 6 of the present invention.

### MODE FOR CARRYING OUT THE INVENTION

Hereinafter, embodiments of manufacturing methods for photovoltaic power devices and manufacturing apparatuses for photovoltaic power devices according to the present invention will be described in detail with reference to the drawings.

### Embodiment 1

There will be described an outline of laser machining for forming a texture structure on a surface (solar light incident surface) of a single-crystal silicon solar cell in a manufacturing method and manufacturing apparatus for a photovoltaic power device according to this embodiment. Here, the texture structure is a concavity and convexity structure provided on a surface of a single-crystal silicon substrate, which is effective in suppressing light reflection since incident solar light is absorbed with multiple reflection in the concavity and convexity structure on the substrate surface. By forming the texture structure on the surface of the single-crystal silicon solar cell, the light reflection on the surface is suppressed and photoelectric conversion efficiency can be improved.

Hereinafter, there will be described in detail, among manufacturing processes of a single-crystal silicon solar cell, a process for forming a texture structure on a surface of the single-crystal silicon solar cell, which is the process related to the present invention.

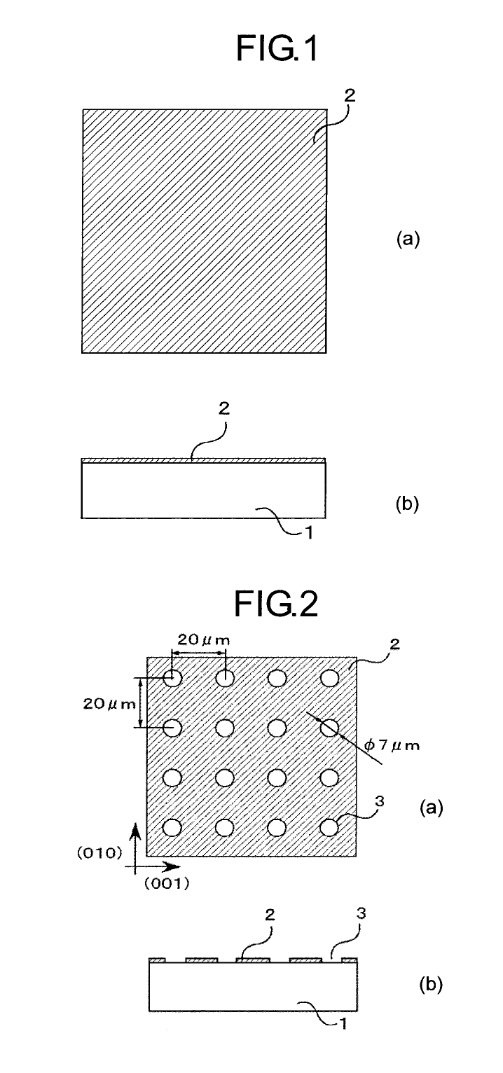

First, a general process flow for forming a texture structure will be described with reference to FIG. 1 through FIG. 3. FIGS. 1 to 3 are schematic diagrams for describing a general process for forming the texture structure of the single-crystal silicon solar cell. In these figures, (a) part of each figure shows a top view when viewed from a light incident surface, and (b) part shows a cross-sectional view when the light incident surface is faced up.

In forming the texture structure, there is used a p-type or n-type single-crystal silicon substrate which is commonly used, having typical specifications of 0.1-10 Ωcm in specific resistance when sliced along a (1 0 0) plane and 200-400 μm in thickness. An etching resistance film 2 having wet etching resistance is formed on the entire front surface of a single-crystal silicon substrate 1 so that patterning of an electrode pattern or the like by a laser is possible. As the etching resistance film 2, a silicon nitride film (Si₃N₄ film), for example, is used ((a) of FIG. 1 and (b) of FIG. 1). Note that in addition to the silicon nitride film (Si₃N₄ film), a silicon oxide film (SiO₂ film) and the like can be used as the etching resistance film 2, which has sufficient etch selectivity between the silicon and the film in alkali etching.

Next, in the etching resistance film 2, laser aperture portions 3 are formed which are aligned to have a geometrical periodic structure (FIG. 2). The laser aperture portions 3 are formed on square lattice dots with 20 μm pitch in a direction parallel to planes of (0 1 0) and (0 0 1).

A diameter of each laser aperture portion 3 is set to be approximately 7 μm. The diameter of the laser aperture portion 3 is determined based on laser intensity to be used and a beam condensing spot diameter on the silicon substrate. As described later, productivity in an etching process is improved by enlarging the laser aperture portion 3.

In order to obtain a large laser aperture portion 3, it may be helpful to increase the laser intensity radiated to one laser aperture and, at the same time, to enlarge the beam condensing spot diameter on the silicon substrate. While a laser machining diameter can be enlarged by enlarging the laser beam condensing spot diameter, laser intensity per unit area decreases when the laser beam condensing spot diameter is enlarged without changing the laser intensity. When the laser intensity per unit area decreases, it is impossible to form the aperture because a temperature rise on the substrate surface by the laser radiation becomes insufficient.

In laser machining, a method of performing the concurrent multipoint laser machining by splitting the laser beam is one effective means to achieve high-speed laser machining. On the other hand, in order to increase the laser intensity radiated to one laser aperture, it is necessary to decrease the splitting number of the laser beam, and the productivity in the laser machining process is degraded when the splitting number is decreased. Here, from the standpoint of placing the highest priority on a laser machining productivity requirement, the diameter of the laser aperture is set to be around 7 μm as a result of a trade-off between these two factors.

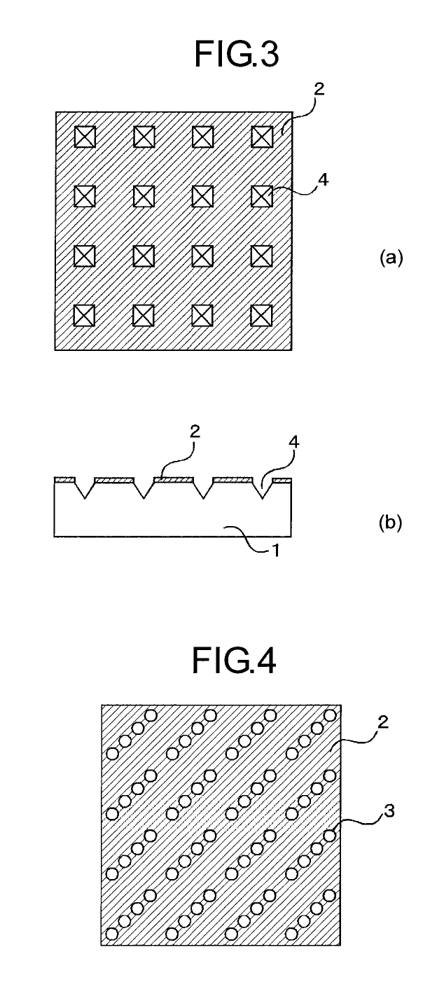

Following that, anisotropic wet etching is performed on the single-crystal silicon substrate 1 through the laser aperture portions 3 with an alkaline etchant such as a solution of potassium hydroxide (KOH) or sodium hydroxide (NaOH). In the usual anisotropic wet etching, an etching speed in a (1 1 1) plane is extremely slow compared to etching speeds in other crystal orientations. Therefore, when the anisotropic wet etching with the alkaline solution is performed on the single-crystal silicon substrate sliced along a (1 0 0) plane, the substrate is anisotropically etched along the (1 1 1) plane and a pyramid concavity 4 is obtained which is formed with four walls oriented to the (1 1 1) plane and has a V-shaped cross section. When the anisotropic etching is performed through the laser aperture portions 3 formed in the etching resistance film 2, since the anisotropic etching is facilitated in the silicon exposed through the laser aperture portions 3, there are formed, by the etching in a relatively short time period, the pyramid concavities having squares circumscribing the laser aperture portions 3 as their bases and being formed with the four walls oriented to the (1 1 1) plane (FIG. 3).

When the pyramid concavity is formed by exposure of the planes oriented to the (1 1 1) plane as described above, since the etching speed in the (1 1 1) plane is slow in the anisotropic etching, a speed decreases in enlarging the size of the concavity typically represented by the side length of the square to be the pyramid base and the height of the pyramid.

Meanwhile, an area between the adjacent pyramid concavities has almost no effect in reducing reflectance since the silicon substrate surface thereof is flat. Therefore, in order to form a texture structure having a sufficient effect in reducing the reflectance as a whole, it is necessary to make the interval between the pyramid concavities sufficiently narrower than the pyramid size.

As described above, since the speed in enlarging the size of the pyramid concavity by the anisotropic etching is significantly reduced, it is necessary to perform the etching for long hours or to enlarge the area of the laser aperture portion 3 in order to sufficiently narrow the interval between the pyramid concavities.

When the etching for long hours is performed, degradation of etching process productivity itself becomes a problem and, in addition, there arises size variability in the pyramid concavity due to etching conditions such as the temperature and concentration of etching liquid, which vary during the etching for long hours. As a result, while the interval between the pyramid concavities is kept large in some areas of the substrate, a ridgeline is flattened by the adjacent pyramid concavities connecting together in other areas, which causes a problem of decreasing the effect in reducing the reflectance.

On the other hand, when the area of the laser aperture portion 3 is enlarged, in addition to the problem of degrading the productivity in the laser machining process, pyramid concavity sizes become non-uniform due to shape variability of the aperture diameters of the laser aperture portions 3, as described above. Although it is ideal that the laser aperture portions 3 are complete circles of the same size when viewed from a laser beam incident side of the silicon substrate, there actually happens a case in which the diameters thereof vary within a range of up to approximately 30% of the diameter or a case in which a shape of the complete circle becomes an ellipse, due to an aberration specific to an optical system of the laser beam machine for forming the laser apertures and the thickness variability of the wafer. The size variability of the pyramid concavities due to the shape variability of the laser aperture portions 3 causes a problem of decreasing the effect in reducing the reflectance, similar to that caused by the etching for long hours. Also, a high intensity laser is necessary to enlarge the area of the laser aperture portion 3. When the high intensity laser is radiated, a problem also arises in which characteristics of a manufactured photovoltaic power device deteriorate, because there remains damage which was formed in the silicon substrate by heat generated in the silicon substrate under the laser beam radiation and has not been completely removed by the etching.

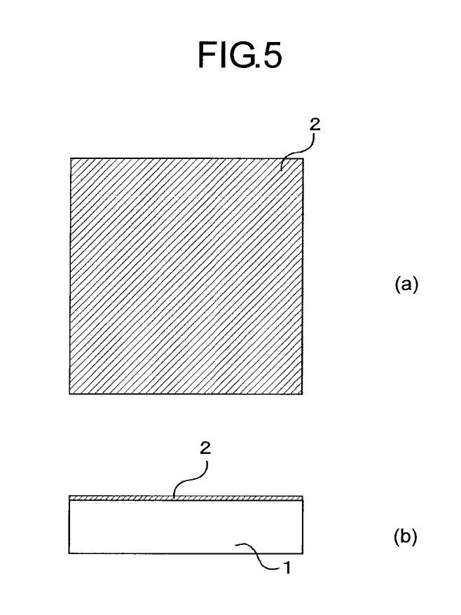

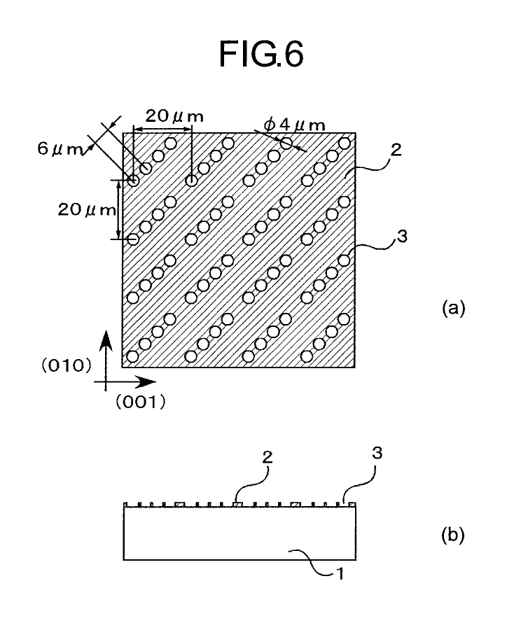

Therefore, in this embodiment, by setting one laser aperture portion 3 consisting of four apertures as a unit as shown in FIG. 4, the laser aperture portions 3 are formed on the substrate as densely as possible. In this case, while one intended pyramid concavity shown in (a) of FIG. 8 is finally formed based on the laser aperture portion 3 (in (a) of FIG. 8, 16 of such pyramid concavities are formed in total), the laser aperture portions 3 are formed on a diagonal of a base square of the pyramid concavity and these diagonals are formed in parallel separated by a predetermined distance with each other ((a) of FIG. 6).

FIG. 4 is a diagram for describing a pattern of laser aperture portions according to Embodiment 1 of the present invention. Four laser apertures for forming one pyramid concavity are formed being separated by a predetermined distance from four laser aperture portions 3 for forming the adjacent pyramid concavities. The interval between the pyramid concavities to be formed is controllable by controlling the distance (concretely, the distance shown as 20 μm in (a) of FIG. 6). In other words, the pattern of the laser aperture portions 3 is formed based on a relatively narrow pitch for dividing the diagonal of the pyramid concavity (6 μm pitch in the example of the present invention) and a relatively wide pitch for determining the interval between the pyramid concavities (20 μm pitch in the example of the present invention).

A texture structure forming procedure according to the present laser aperture pattern will be described with reference to FIG. 5 through FIG. 8.

Similar to the case in the general method, a silicon nitride film (Si₃N₄ film) or a silicon oxide film (SiO₂) is formed on the entire front surface of the single-crystal silicon substrate 1 as the etching resistance film 2 having the wet etching resistance (FIG. 5).

Following that, the laser aperture portions 3 are formed in the etching resistance film 2 by the laser beam (FIG. 6).

At this time, as shown in FIG. 6, a set of four apertures is formed on the (1 1 1) plane with 6 μm pitch in a direction at 45 degrees to a (0 0 1) direction (a diagonal direction of a square to be a base of the pyramid concavity which will be formed later in the etching process), and multiple sets of the laser aperture portions 3 are formed with 20 μm pitch in each side direction of the square to be the base of the pyramid concavity.

Compared to the general method case, the number of the laser aperture portions 3 formed in one silicon substrate increases fourfold. In order not to degrade the productivity in the laser machining process, it is necessary to increase a splitting number of the laser beam. When the splitting number of the laser beam is increased for this purpose, since there is decreased the laser intensity radiated for forming one of four apertures of the laser aperture portion 3, it is necessary for removing the film to condense the laser beam in a small diameter on the silicon substrate and to set the diameter of the laser aperture portion 3 small. Here a diameter of 4 μm is employed. By decreasing the diameter of the laser aperture portion 3 commensurate with the increase in number of machining points, the laser apertures can be formed without degrading the laser machining productivity. As a representative value of the aperture size, a diameter of 4 μm±1 μm is given as a guide. A concrete means to form a periodic pattern composed of such two kinds of pitches will be described later.

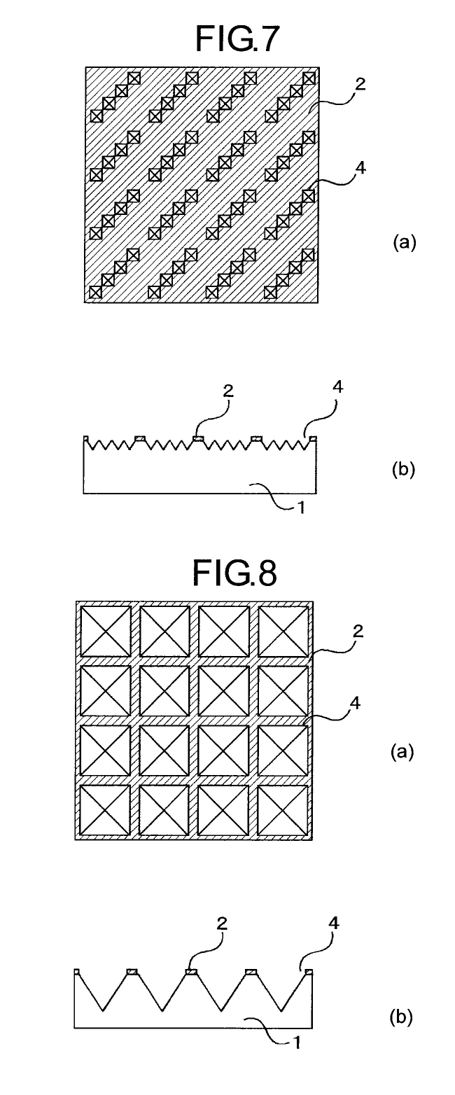

After that, similar to the general method case, the anisotropic etching is performed on the single-crystal silicon substrate 1 through the laser aperture portions 3. By the etching in a short time period, there are formed the pyramid concavities each having, as its base, a square circumscribing the circular shape of each laser aperture portion 3 (FIG. 7).

After the pyramid concavities are formed, enlarging of the pyramid concavity size proceeds very slowly. While the etching speed decreases, the pyramid concavities which are formed in accordance with the laser aperture portion 3 consisting of a set of four apertures formed in the laser aperture forming process are coupled by the etching of a relatively short time period because the gap between the pyramid concavities is sufficiently narrow. In an area where the ridgelines are coupled, the etching again proceeds rapidly because planes other than the (1 1 1) plane are exposed. As a result, there is formed a large pyramid concavity formed from four laser apertures as shown in FIG. 8. The etching time is around one fifth when compared to that in the general method, and it is possible to form the texture structure having the uniform pyramid concavities. After forming the texture structure, etching for removing the etching resistance film 2 is performed if necessary.

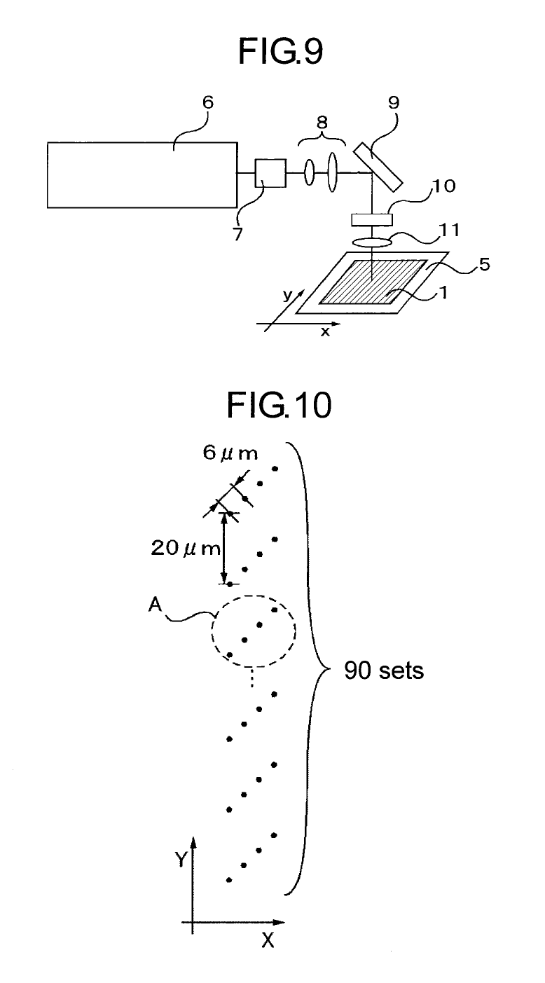

Next, a concrete method to form the laser aperture pattern shown in FIG. 6 will be described. A schematic configuration diagram of laser machining equipment for forming the laser aperture pattern is shown in FIG. 9. The laser machining equipment is provided with a silicon substrate conveyance means 5, a laser oscillator 6, a laser beam intensity adjustment means 7, a laser beam profile adjustment means 8, one or more light guiding mirrors 9, a laser beam splitting means 10, and a laser beam condensing means 11.

The silicon substrate conveyance means 5 holds the single-crystal silicon substrate 1, with its surface to be machined facing upward, on whose surface the etching resistance film (not shown in the figure) has been formed, and conveys the single-crystal silicon substrate 1 along a laser beam condensing plane.

The laser oscillator 6 radiates a laser beam. The laser oscillator 6 may use a second order harmonic (wave length of 532 nm) of an LD pumped Q-switch Nd:YVO4 laser having a typical repetition frequency of, for example, 40 kHz. When an ultraviolet laser such as a third order harmonic or a fourth order harmonic is used, while high-grade machining of smaller diameter holes is possible due to its high absorption coefficient in the etching resistance film and the silicon, the laser intensity decreases and, additionally, there arises a problem of degrading optical elements caused by the influence of impurities in the air. An appropriate wavelength may be selected by considering advantages and disadvantages. Here, the laser beam intensity adjustment means 7 is a means of attenuating the laser intensity automatically or manually to get laser intensity suitable for machining.

The laser beam profile adjustment means 8 is configured with a combination of cylindrical lenses to get a complete circle laser beam profile and a combination of spherical lenses to get an intended beam diameter and beam divergence angle.

As for the light guiding mirror 9, while one mirror is arranged between the laser beam profile adjustment means 8 and the laser beam splitting means 10 in FIG. 9, one or more mirrors are arranged appropriately to optically guide the laser beam in accordance with a laser beam machine space size.

The laser beam splitting means 10 splits the laser beam into a laser beam splitting pattern having a predetermined geometrical periodic structure shown in FIG. 10. FIG. 10 is a schematic diagram showing the laser beam splitting pattern. Each center of the split laser beams is shown in a black circle in FIG. 10. As for the laser beam splitting pattern, a pattern is employed in which 90 sets of splitting patterns each consisting of four points with 6 μm pitch (shown as “A” in FIG. 10) are aligned with 20 μm pitch in a direction at 45 degrees to an aligned direction of the 6 μm pitch splitting pattern (shown as a Y direction in FIG. 10).

For example, a diffractive optical element may be used as the laser beam splitting means 10. Although a multi-aperture mask, for example, may be used as another laser beam splitting means, it is preferable to use the diffractive optical element from a standpoint of beam uniformity and efficiency.

The laser beam split by the laser beam splitting means 10 is condensed on the single-crystal silicon substrate 1 by the laser beam condensing means 11. By conveying the single-crystal silicon substrate 1 in a direction shown as an x direction in FIG. 9 at a speed of 800 mm per second with the single-crystal silicon substrate conveyance means 5 concurrently with pulse oscillating the laser oscillator 6 at 40 kHz, the laser beam is to be radiated on the single-crystal silicon substrate 1 with a pitch of 800 mm/40 kHz=20 μm, so that the pattern of the laser aperture portions 3 shown in FIG. 6 can be formed. Here, the y direction and x direction in FIG. 9 are oriented to the X direction and Y direction in FIG. 10, respectively.

While the single-crystal silicon substrate 1 is conveyed by the single-crystal silicon substrate conveyance means 5 when scanning the laser beam on the single-crystal silicon substrate 1, a similar effect can be obtained by scanning the laser beam, on the single-crystal silicon substrate 1, which is split by the laser beam splitting means using a galvanometer mirror as a laser beam deflection means and an Fθ lens as a beam condensing means. Since a method of scanning the laser beam enables a faster scan than a method of conveying an object to be machined with the conveyance means in general, productivity in laser machining can be improved if the laser intensity and the repetition frequency are appropriately selected.

Note that the numerical values shown in the above description are typical values to achieve the present invention, and it is needless to say that the effect of the present invention is not limited to the case of using such values. For example, 6 μm may be substituted by 12 μm and 20 μm may be substituted by 40 μm.

### Embodiment 2

In this embodiment, an inverse pyramid concavity and convexity structure is formed on the single-crystal silicon solar cell surface for the purpose of reducing solar light reflectance by forming an etching resistance film on a single-crystal silicon solar cell surface and forming laser apertures in the etching resistance film and performing wet etching. Because only a laser machining process is different from that in Embodiment 1, the description below will be focused on the laser machining process.

In Embodiment 1, the narrowest pitch in the laser beam splitting pattern is set to be 6 μm as shown in FIG. 10. Corresponding to the pitch, the laser beam condensing spot diameter on the single-crystal silicon substrate 1 is set to be 4 μm. In such a case in which the narrowest pitch in the laser beam splitting pattern is no more than twice the diameter of the laser beam condensing spot, a problem of deteriorating the shape of the laser aperture portion 3 may arise because a beam pattern of an actually condensed laser beam deviates from a complete circle and becomes an ellipse or the like due to interference between the adjacent laser beams with each other.

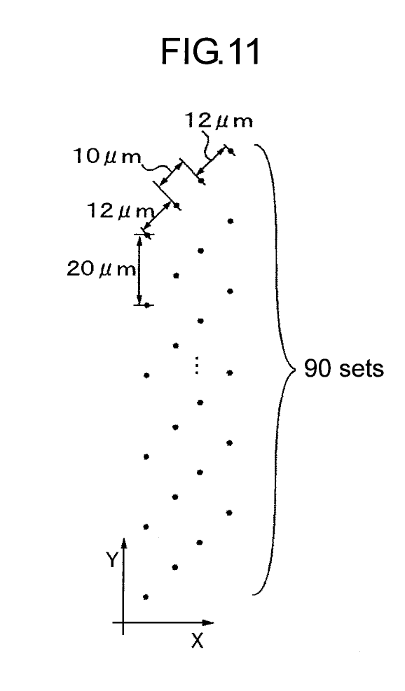

A laser beam splitting pattern according to this embodiment is shown in FIG. 11. In the laser beam splitting pattern, a distance between the closest pair of points is 10 μm. Since the distance between the closest pair of points is no less than twice the laser beam condensing spot diameter on the single-crystal silicon substrate 1, i.e. 4 μm, the problem of deteriorating the laser aperture shape does not arise.

When conveyed in the X direction with a pitch of 20 μm, a laser aperture pattern similar to that in (a) of FIG. 6 can be machined by using the laser beam splitting pattern. A laser repetition frequency is to be 40 kHz and a conveying speed of the single-crystal silicon substrate 1 with the silicon substrate conveyance means 5 is to be 800 mm per second in order to perform the machining by using the laser beam machine shown in FIG. 9.

By performing the etching and the following processes similar to those in Embodiment 1, the texture structure having the pyramid concavities shown in FIG. 8 can be formed.

Note that the numerical values shown in the above description are typical values to achieve the present invention, and it is needless to say that the effect of the present invention is not limited to the case of using such values.

### Embodiment 3

In this embodiment, because only a laser machining process is different from that in Embodiment 1, the description below will be focused on the laser machining process.

In Embodiment 1 and Embodiment 2, the laser beam splitting patterns are formed with two kinds of pitches as shown in FIG. 10 and FIG. 11. In design and manufacturing of a diffractive optical element for splitting the laser beam, when two kinds of pitches are mixed, a lattice having the greatest common divisor of them as its pitch is set, and the two kinds of pitches are depicted by whether or not the laser beam is arranged on each of lattice dots. For example, when 12 μm pitch and 18 μm pitch are mixed, a lattice of 6 μm pitch is set, and the 12 μm pitch is depicted as every other lattice dots and the 18 μm pitch is depicted as every third lattice dots. When the lattice pitch is small, a surface profile pitch of the diffractive optical element enlarges, and it is necessary to set an incident laser beam to the diffractive optical element larger.

In a case of using an Fθ lens as a beam condensing lens, when the incident laser beam becomes large, the beam cannot be treated as a paraxial ray because the beam passes through a peripheral portion of the lens, and a problem arises that the design and manufacturing becomes difficult.

Therefore, in this embodiment, a laser beam splitting pattern, laser pulse timing, and a plane direction of the single-crystal silicon substrate 1 on the silicon substrate conveyance means 5 are changed from those in Embodiments 1 and 2.

FIG. 12 is a schematic diagram for describing a laser beam splitting pattern according to Embodiment 3 of the present invention. In the laser beam splitting pattern, a row of the laser beam split into 68 with 28 μm pitch in the Y direction is employed and two rows of the laser beam, which are shifted 14 μm in the Y direction with each other, are arranged with 14 μm pitch in the X direction.

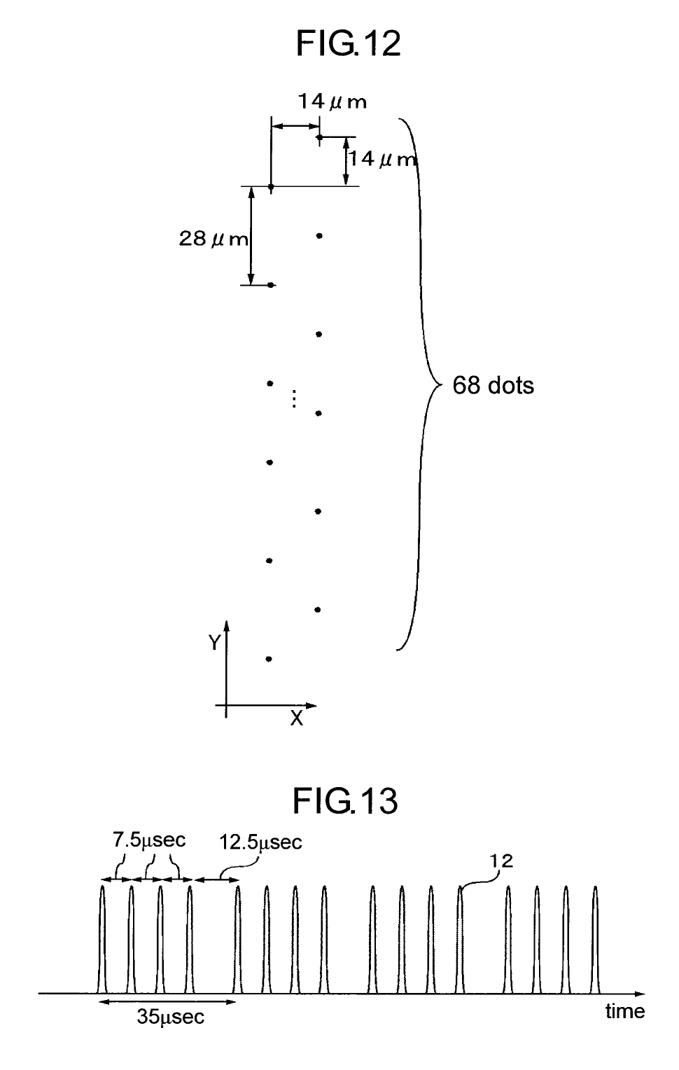

A schematic diagram for describing laser pulse timing according to Embodiment 3 is shown in FIG. 13. Four laser pulses with 7.5 μs interval make a set. By generating the sets of the laser pulses with 35 μs pitch, laser pulse rows are provided under the timing shown in FIG. 13

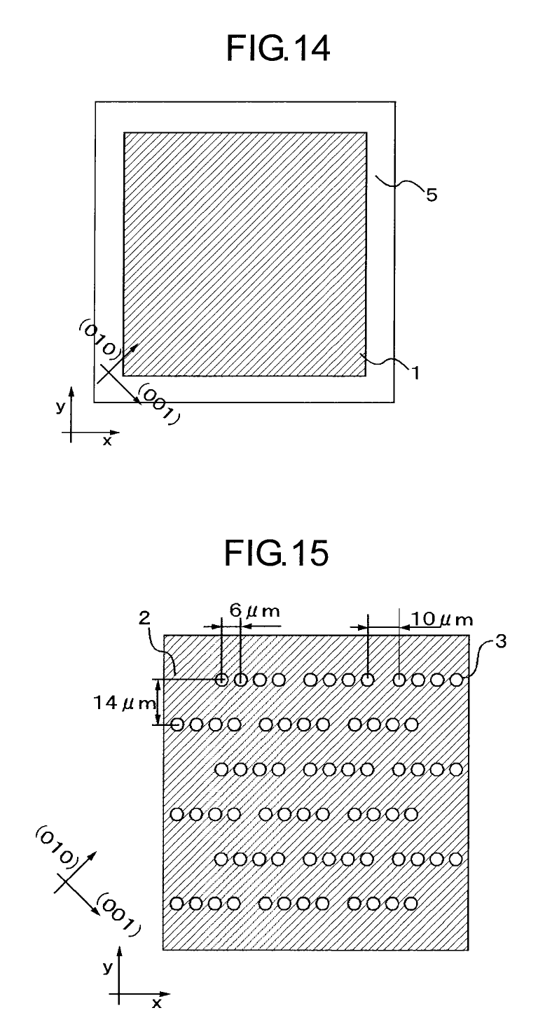

The plane direction of the single-crystal silicon substrate 1 on the silicon substrate conveyance means 5 is arranged so that a (0 1 0) plane and a (0 0 1) plane thereof are set at 45 degrees to four sides of the single-crystal silicon substrate 1. The plane direction of the single-crystal silicon substrate 1 on the silicon substrate conveyance means 5 according to embodiments of the present invention is shown in FIG. 14.

Here, a conveyance speed in the x direction shown in FIG. 9 is set to be 800 mm per second similar to those in Embodiments 1 and 2.

In FIG. 15, there is shown a pattern of laser aperture portions 3 which is machined when the single-crystal silicon substrate 1 is conveyed in the x direction at 800 mm per second using the laser beam splitting pattern shown in FIG. 12 and employing the laser pulse timing shown in FIG. 13. FIG. 15 is a schematic diagram for describing the pattern of laser aperture portions according to Embodiment 3 of the present invention. The beam condensing spot diameter and the laser intensity on the silicon substrate are adjusted so that the diameter of the laser aperture portion 3 is to be 4 μm.

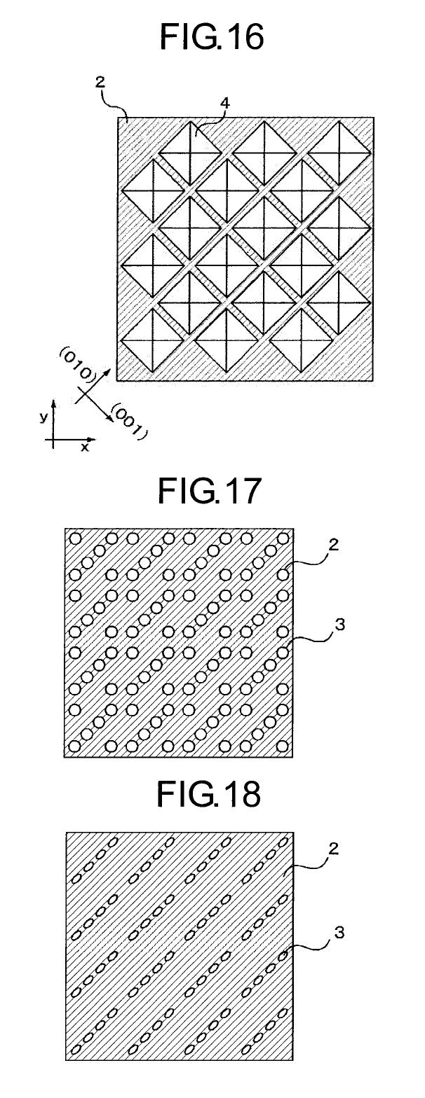

As a result of performing the anisotropic etching on the laser aperture portions 3 obtained by this embodiment, a texture structure having pyramid concavities as shown in FIG. 16 can be formed. FIG. 16 is a schematic diagram for describing the texture structure according to Embodiment 3 of the present invention.

Note that the numerical values shown in the above description are typical values to achieve the present invention, and it is needless to say that the effect of the present invention is not limited to the case of using such values.

### Embodiment 4

In this embodiment, because only a laser machining process is different from that in Embodiment 1, the description below will be focused on the laser machining process. A laser aperture pattern in Embodiment 4 is shown in FIG. 17. In Embodiment 1 through Embodiment 3, the laser aperture portion is configured with the laser apertures formed on the diagonal of the square to be the base of the quadrangular pyramid concavity to be formed. In this way, by forming the laser apertures on one diagonal, there can be obtained the concavity for connecting the diagonal of the intended texture structure with the small areas of the laser apertures and the etching in a short time period. When thinking simplistically, since the laser machining speed is inversely proportional to the entire areas of the laser apertures, the speed can be increased when the area of the laser apertures is small.

On the other hand, when the laser apertures are formed on the diagonal in this way, there is necessary a certain amount of etching time for enlarging the concavity in a direction of a diagonal perpendicular to the diagonal on which the laser apertures are formed. When required takt time for the etching is short and laser output has a power to spare compared to required takt time for the laser machining, the etching time can be reduced because the time for enlarging the concavity can be reduced by forming the laser apertures also on portions other than the diagonal as shown in FIG. 17.

### Embodiment 5

In this embodiment, because only a laser machining process is different from that in Embodiment 1, the description below will be focused on the laser machining process. A laser aperture pattern in Embodiment 5 is shown in FIG. 18. In Embodiment 1 through Embodiment 4, the laser aperture shape is set to be the complete circle. On the other hand, the laser aperture shape is set to be an ellipse in this embodiment. It is apparent, from the comparison with the case in which the laser aperture shape is the complete circle shown in FIG. 4, that the area of the laser apertures can be reduced. Reducing the area of the laser apertures and improving the takt time in the laser machining are substantially equivalent.

The reason is as follows.

When the area of the laser apertures is reduced, since the machining is to be performed by condensing the laser beam in a smaller area, the laser energy density per unit area can be increased for the same laser power and the same splitting number of the laser beam. When the laser energy density necessary for machining the etching resistance film is set as the laser energy density of machining, it is possible to get a larger splitting number of the laser beam for the same laser power. By increasing the splitting number of the laser beam, the takt time in the laser machining can be improved.

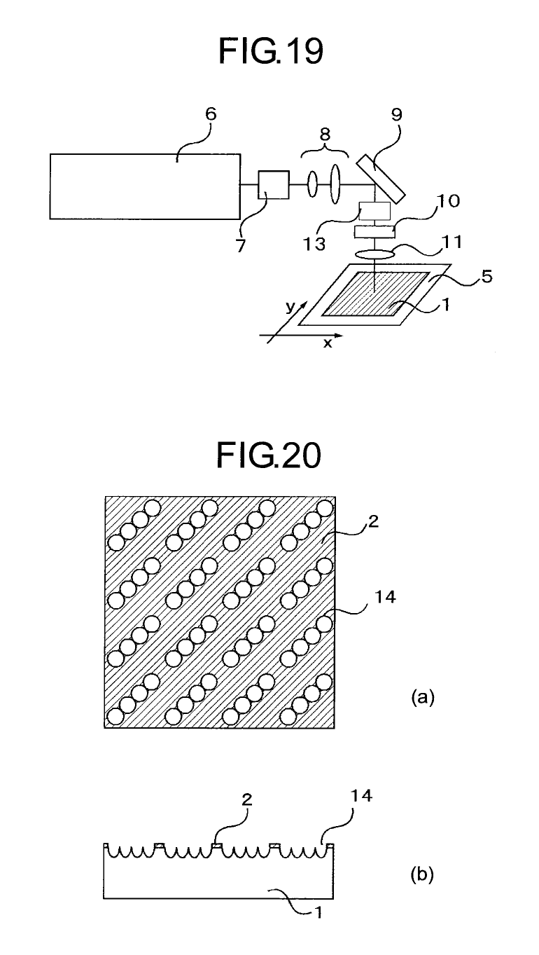

FIG. 19 is a schematic configuration diagram of laser machining equipment for forming the laser aperture pattern according to Embodiment 5 of the present invention. A cylindrical surface lens and a prism can be used for an elliptic optical system 13 for forming the laser aperture shape to be elliptical.

### Embodiment 6

In this embodiment, because only a wet etching process is different from that in Embodiment 1, the description below will be focused on the wet etching process. In Embodiment 1, only the anisotropic alkali etching is employed as the wet etching. Meanwhile, a wet etching process is divided into processes of two or more steps in this embodiment. As the wet etching process, an isotropic etching with mixed acid or the like is performed first, and then an anisotropic alkali etching is performed. Because the etching speed of enlarging the concavity is significantly reduced when encountering a (1 1 1) plane in the anisotropic etching, it requires a long etching time to connect small pyramid concavities originated from the adjacent laser apertures after encountering the (1 1 1) plane. On the other hand, as shown in (a) of FIG. 20 and (b) of FIG. 20, since bowl shaped concavities are formed without the influence of a crystal orientation in the isotropic etching, it is possible within a relatively short time period to connect the concavities originated from the adjacent laser apertures. (a) of FIG. 20 is a diagram in which the solar cell is viewed from its light reception surface side, and (b) of FIG. 20 is a cross sectional view of the solar cell. Therefore, the etching time can be reduced. Also, by further performing an etching with an alkali which contains an additive such as IPA after performing the anisotropic alkali etching, collapse of boundaries of the pyramid concavities with the etching can be prevented when the adjacent pyramid concavities are connected.

### REFERENCE NUMERALS

1: single-crystal silicon substrate, 2: etching resistance film, 3: laser aperture portion, 4: pyramid concavity, 5: silicon substrate conveyance means, 6: laser oscillator, 7: laser intensity adjustment means, 8: laser beam profile adjustment means, 9: light guiding mirror, 10: laser beam splitting means, 11: laser beam condensing means, 12: laser pulse, 13: elliptic optical system, and 14: bowl shaped concavity.

1. A manufacturing method for a photovoltaic power device in which a single-crystal silicon substrate is used and a reflection preventing texture is formed on a surface of the photovoltaic power device by using laser patterning of an etching resistance film and wet etching, the manufacturing method comprising:
a first process for forming a laser aperture portion consisting of a plurality of apertures by the laser patterning; and
a second process, after forming the same number of quadrangular pyramid concavities as the plurality of apertures with the wet etching, that have square shaped bases based on the plurality of respective apertures and have shapes of inverse pyramids when viewed from a front surface side of the single-crystal silicon substrate, for forming a quadrangular pyramid concavity that contains all of the plurality of quadrangular pyramid concavities having the same number as the apertures and has a dimension substantially x times (x: the number of the plurality of quadrangular pyramid concavities contained in a square shaped base of the quadrangular pyramid concavity to be formed) as large as each of the quadrangular pyramid concavities.

2. A manufacturing method for a photovoltaic power device in which a single-crystal silicon substrate is used and a reflection preventing texture is formed on a surface of the photovoltaic power device by using laser patterning of an etching resistance film and wet etching, the manufacturing method comprising:
a first process for forming a laser aperture portion consisting of a plurality of apertures by the laser patterning; and
a second process, after forming the same number of quadrangular pyramid concavities as the plurality of apertures with the wet etching, that have square shaped bases based on the plurality of respective apertures and have shapes of inverse pyramids when viewed from a front surface side of the single-crystal silicon substrate, for forming a quadrangular pyramid concavity that contains all of the plurality of quadrangular pyramid concavities having the same number as the apertures and has a dimension substantially x times (x: the number of the plurality of quadrangular pyramid concavities contained in a square shaped base of the quadrangular pyramid concavity to be formed) as large as each of the quadrangular pyramid concavities in a direction in which all of the quadrangular pyramid concavities are connected in a straight line out of diagonal directions of the square shaped bases of the quadrangular pyramid concavities.

3. The manufacturing method for the photovoltaic power device of claim 2, wherein
a laser beam used for the laser patterning is a pulse laser;
the laser patterning is performed by using the pulse laser and a laser beam splitting means for splitting the laser beam into a laser beam splitting pattern having a predetermined geometrical periodic structure; and
when laser aperture portions each consisting of the plurality of laser apertures are formed, a shortest pitch between the aperture portions of the laser aperture portions is set to be larger than a shortest pitch between arbitrary two laser apertures belonging to one of the laser aperture portions.

4. The manufacturing method for the photovoltaic power device of claim 3, wherein, in the laser beam splitting pattern, a distance between the adjacent laser beams is set to be no less than twice a laser beam condensing spot diameter.

5. The manufacturing method for the photovoltaic power device of claim 3, wherein a pitch of the laser beam splitting pattern is set to be a single value and the laser patterning is performed by adjusting laser pulse timing.

6. The manufacturing method for the photovoltaic power device of claim 3, wherein, regarding a pitch between the laser apertures of the laser aperture portion, one or more sets of apertures consisting of a set of at least two apertures having the same pitch are included.

7. The manufacturing method for the photovoltaic power device of claim 1, wherein a shape of the laser apertures of the laser aperture portion is a slender shape having a direction large in their size and a direction small in their size.

8. The manufacturing method for the photovoltaic power device of claim 1, wherein the wet etching is configured with two or more types of etching in which etching liquid composition therefor is varied.

9. A manufacturing apparatus for a photovoltaic power device in which a single-crystal silicon substrate is used and a reflection preventing texture is formed on a surface of the photovoltaic power device by using laser patterning of an etching resistance film and wet etching, wherein
a laser aperture portion consisting of a plurality of apertures is formed by the laser patterning; and
after forming the same number of quadrangular pyramid concavities as the plurality of apertures with the wet etching, that have square shaped bases based on the plurality of respective apertures and have shapes of inverse pyramids when viewed from a front surface side of the single-crystal silicon substrate, a quadrangular pyramid concavity is formed that contains all of the plurality of quadrangular pyramid concavities having the same number as the apertures and has a dimension substantially x times (x: the number of the plurality of quadrangular pyramid concavities contained in a square shaped base of the quadrangular pyramid concavity to be formed) as large as each of the quadrangular pyramid concavities in a direction in which all of the quadrangular pyramid concavities are connected in a straight line out of diagonal directions of the square shaped bases of the quadrangular pyramid concavities.

10. The manufacturing apparatus for the photovoltaic power device of claim 9, wherein
a laser beam used for the laser patterning is a pulse laser;
the laser patterning is performed by using the pulse laser and a laser beam splitting means for splitting the laser beam into a laser beam splitting pattern having a predetermined geometrical periodic structure; and
when laser aperture portions each consisting of the plurality of laser apertures are formed, a shortest pitch between the aperture portions of the laser aperture portions is set to be larger than a shortest pitch between arbitrary two laser apertures belonging to one of the laser aperture portions.

11. The manufacturing method for the photovoltaic power device of claim 2, wherein a shape of the laser apertures of the laser aperture portion is a slender shape having a direction large in their size and a direction small in their size.

12. The manufacturing method for the photovoltaic power device of claim 3, wherein a shape of the laser apertures of the laser aperture portion is a slender shape having a direction large in their size and a direction small in their size.

13. The manufacturing method for the photovoltaic power device of claim 2, wherein the wet etching is configured with two or more types of etching in which etching liquid composition therefor is varied.

14. The manufacturing method for the photovoltaic power device of claim 3, wherein the wet etching is configured with two or more types of etching in which etching liquid composition therefor is varied.

15. The manufacturing method for the photovoltaic power device of claim 4, wherein the wet etching is configured with two or more types of etching in which etching liquid composition therefor is varied.

16. The manufacturing method for the photovoltaic power device of claim 5, wherein the wet etching is configured with two or more types of etching in which etching liquid composition therefor is varied.

17. The manufacturing method for the photovoltaic power device of claim 6, wherein the wet etching is configured with two or more types of etching in which etching liquid composition therefor is varied.

18. The manufacturing method for the photovoltaic power device of claim 7, wherein the wet etching is configured with two or more types of etching in which etching liquid composition therefor is varied.

19. The manufacturing method for the photovoltaic power device of claim 8, wherein the wet etching is configured with two or more types of etching in which etching liquid composition therefor is varied.

20. The manufacturing method for the photovoltaic power device of claim 9, wherein the wet etching is configured with two or more types of etching in which etching liquid composition therefor is varied.
